(19) United States
(12) Patent Application Publication
(10) Pub. No.: US 2015/0021563 A1
(43) Pub. Date: Jan. 22, 2015

(54) COMPOUND FOR ORGANIC OPTOELECTRONIC DEVICE, ORGANIC LIGHT EMITTING DIODE INCLUDING THE SAME AND DISPLAY INCLUDING THE ORGANIC LIGHT EMITTING DIODE

(71) Applicants: RESEARCH & BUSINESS FOUNDATION SUNGKYUNKWAN UNIVERSITY, Suwon-si (KR); SAMSUNG DISPLAY CO., LTD., Yongin-City (KR)

(72) Inventors: Jae-Hong Kim, Yongin-City (KR); Myeong-Suk Kim, Yongin-City (KR); Soung-Wook Kim, Yongin-City (KR); Sam-il Kho, Yongin-City (KR); Seung-Soo Yoon, Suwon-si (KR)

(73) Assignees: RESEARCH & BUSINESS FOUNDATION SUNGKYUNKWAN UNIVERSITY, Suwon-si (KR); SAMSUNG DISPLAY CO., LTD., Yongin-City (KR)

(21) Appl. No.: 14/105,165

(22) Filed: Dec. 12, 2013

(30) Foreign Application Priority Data
Jul. 16, 2013 (KR) 10-2013-0083780

(51) Int. Cl. H01L 51/00

(52) U.S. Cl. CPC H01L 51/0074
USPC 257/40; 549/41

(57) ABSTRACT

Disclosed are a compound for an organic optoelectronic device, an organic light emitting diode including the same, and a display device including the organic light emitting diode, and the compound is represented by the following Chemical Formula 1.

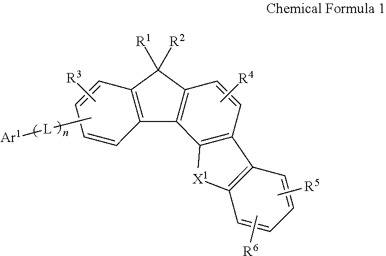

### CROSS-REFERENCE TO RELATED APPLICATION

This application claims priority to and the benefit of Korean Patent Application No. 10-2013-0083780, filed in the Korean Intellectual Property Office on Jul. 16, 2013, the entire content of which is incorporated herein by reference.

### BACKGROUND

1. Field

A compound for an organic optoelectronic device, an organic light emitting diode including the same, and a display device including the same are disclosed.

2. Description of the Related Art

An organic photoelectronic device is a device requiring a charge exchange between an electrode and an organic material by using holes or electrons.

An organic optoelectronic device may be classified as follows in accordance with its driving principles. A first organic optoelectronic device is an electronic device driven as follows: excitons are generated in an organic material layer by photons from an external light source; the excitons are separated into electrons and holes; and the electrons and holes are transferred to different electrodes as a current source (voltage source).

A second organic optoelectronic device is an electronic device driven as follows: a voltage or a current is applied to at least two electrodes to inject holes and/or electrons into an organic semiconductor material positioned at interfaces of the electrodes, and the device is driven by the injected electrons and holes.

Examples of an organic optoelectronic device include an organic photoelectric device, an organic light emitting diode, an organic solar cell, an organic photo conductor drum, an organic transistor, and the like, which require a hole injecting or transport material, an electron injecting or transport material, or a light emitting material.

Particularly, an organic light emitting diode (OLED) has recently drawn attention due to an increase in demand for flat panel displays. In general, organic light emission refers to the conversion of electrical energy into photo-energy.

Such an organic light emitting diode converts electrical energy into light by applying current to an organic light emitting material. It has a structure in which a functional organic material layer is interposed between an anode and a cathode. The organic material layer includes a multi-layer including different materials, for example a hole injection layer (HIL), a hole transport layer (HTL), an emission layer, an electron transport layer (ETL), and an electron injection layer (EIL), in order to improve efficiency and stability of an organic photoelectric device.

In such an organic light emitting diode, when a voltage is applied between an anode and a cathode, holes from the anode and electrons from the cathode are injected to an organic material layer and recombined to generate excitons having high energy. The generated excitons generate light having certain wavelengths while shifting (or returning) to a ground state.

Recently, it has become known that a phosphorescent light emitting material may be used as a light emitting material of an organic light emitting diode in addition to the fluorescent light emitting material. Such a phosphorescent material emits light by transforming (or exciting) the electrons from a ground state to an excited state, non-radiance transitioning of a singlet exciton to a triplet exciton through intersystem crossing, and transitioning (or relaxing) the triplet exciton to a ground state to emit light.

As described above, in an organic light emitting diode, an organic material layer includes a light emitting material and a charge transport material, for example, a hole injection material, a hole transport material, an electron transport material, an electron injection material, or the like.

The light emitting material is classified as blue, green, and red light emitting materials according to the emitted colors, and yellow and orange light emitting materials that emit colors approaching natural colors.

When one (e.g., only one) material is used as a light emitting material, the maximum light emitting wavelength is shifted to a longer wavelength, or the color purity decreases because of interactions between molecules, or the device efficiency decreases because of a light emitting quenching effect. Therefore, a host/dopant system is included as a light emitting material in order to improve the color purity and increase luminous efficiency and stability through energy transfer.

In order to implement excellent performance of an organic light emitting diode, a material constituting an organic material layer, for example, a hole injection material, a hole transport material, a light emitting material, an electron transport material, an electron injection material, or a light emitting material such as a host and/or a dopant, should be stable and have good efficiency. However, development of an organic material layer forming material for an organic light emitting diode has thus far not been satisfactory and thus there is a need for a novel material. This material development is also required for other organic optoelectronic devices.

A low molecular weight organic light emitting diode is manufactured as a thin film using a vacuum deposition method and can have good efficiency and life-span performance. A polymer organic light emitting diode is manufactured using an Inkjet or spin coating method and has an advantage of low initial cost and being large-sized.

Both low molecular weight organic light emitting and polymer organic light emitting diodes have advantages such as self-light emitting, high speed response, wide viewing angle, ultra-thin, high image quality, durability, large driving temperature range, or the like. In particular, they have good visibility due to self-light emitting characteristics compared with a conventional LCD (liquid crystal display) and have an advantage of decreased thickness and weight up to a third of that of an LCD, because they do not need a backlight.

In addition, since they (low molecular weight organic light emitting diodes and polymer organic light emitting diodes) have a response speed 1000 times faster in microsecond unit than LCD, they can realize a perfect motion picture without after-image. Based on these advantages, they have been remarkably developed (and improved) to have 80 times the efficiency and more than 100 times the life-span compared to when they came out for the first time in the late 1980s. Recently, they keep being rapidly developed to be larger in size (such as a 40-inch organic light emitting diode panel).

The organic light emitting diodes are required to simultaneously have improved luminous efficiency and life-span in order to be larger. There has been a need for stable and efficient material for the organic material layer of an organic light emitting diode.

### SUMMARY

Aspects of embodiments of the present invention are directed toward a compound capable of providing an organic optoelectronic device characteristics such as high efficiency, long life-span, or the like.

Aspects of embodiments of the present invention are directed toward an organic light emitting diode including the compound and a display device including the organic light emitting diode.

In one embodiment, a compound for an organic optoelectronic device represented by the following Chemical Formula 1 is provided.

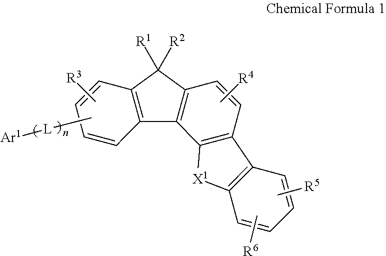

In the above Chemical Formula 1, X¹ is —O—, —S—, or —CR^{a}R^{b}—; Ar¹ is a substituted or unsubstituted C6 to C30 aryl group; R¹ and R² are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; or R¹ and R² are fused with each other to form a ring; R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; L is a substituted or unsubstituted C6 to C30 arylene group; and n is an integer from 0 to 3.

In another embodiment of the present invention, an organic light emitting diode includes an anode; a cathode; and at least one of an organic thin layer between the anode and cathode, wherein the at least one of the organic thin layer includes the above-described compound according to one embodiment of the present invention.

In yet another embodiment of the present invention, a display device including the above-described organic light emitting diode according to one embodiment of the present invention is provided.

In yet another embodiment of the present invention, a display device including the above-described organic light emitting diode according to one embodiment of the present invention is provided. In addition, the compound may be appropriate (suitable) for a solution process.

### BRIEF DESCRIPTION OF THE DRAWINGS

FIGS. 1 to 5 are cross-sectional views showing organic light emitting diodes according to various embodiments of the present invention.

### DETAILED DESCRIPTION

Hereinafter, embodiments are described in more detail. However, these embodiments are only examples, and this disclosure is not limited thereto.

As used herein, when a definition is not otherwise provided, the term “substituted” refers to at least one hydrogen of a substituent or a compound being substituted with deuterium, a halogen, a hydroxy group, an amino group, a substituted or unsubstituted C1 to C30 amine group, nitro group, a substituted or unsubstituted C1 to C40 silyl group, a C1 to C30 alkyl group, a C1 to C10 alkylsilyl group, a C3 to C30 cycloalkyl group, a C6 to C30 aryl group, a C1 to C20 alkoxy group, a fluoro group, a C1 to C10 trifluoroalkyl group such as a trifluoromethyl group or the like, or a cyano group.

In addition, two adjacent substituents of the halogen, hydroxy group, amino group, substituted or unsubstituted C1 to C20 amine group, nitro group, substituted or unsubstituted C3 to C40 silyl group, C1 to C30 alkyl group, C1 to C10 alkylsilyl group, C3 to C30 cycloalkyl group, C6 to C30 aryl group, C1 to C20 alkoxy group, fluoro group, C1 to C10 trifluoroalkyl group such as a trifluoromethyl group or the like, or cyano group may be fused with each other to form a ring.

In the present specification, when specific definition is not otherwise provided, the term “hetero” refers to one compound or substituent including 1 to 3 hetero atoms selected from N, O, S, or P, and the remaining being carbons.

In the present specification, when a definition is not otherwise provided, the term “combination thereof” refers to at least two substituents bound to each other by a linker, or at least two substituents condensed to each other.

As used herein, when a definition is not otherwise provided, the term “alkyl group” may refer to an aliphatic hydrocarbon group. The alkyl group may refer to “a saturated alkyl” without any double bond or triple bond.

The alkyl group may be a C1 to C20 alkyl group. In one embodiment, the alkyl group may be a C1 to C10 alkyl group or a C1 to C6 alkyl group. For example, a C1 to C4 alkyl group includes 1 to 4 carbon in an alkyl chain, and may be selected from methyl, ethyl, propyl, iso-propyl, n-butyl, iso-butyl, sec-butyl, or t-butyl.

Suitable examples of the alkyl group may be a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and the like.

As used herein, the term “aryl group” refers to a substituent including all element of the cycle (or ring) having p-orbitals which form conjugation, and may be monocyclic or fused ring polycyclic (i.e., rings sharing adjacent pairs of carbon atoms) functional group.

As used herein, the term “heteroaryl group” may refer to an aryl group including 1 to 3 hetero atoms selected from N, O, S, or P, and the remaining being carbons in one functional group. The heteroaryl group may be a fused ring where each ring may include the 1 to 3 heteroatoms.

More specifically, the substituted or unsubstituted C6 to C30 aryl group and/or the substituted or unsubstituted C2 to C30 heteroaryl group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenylyl group, a substituted or unsubstituted p-terphenyl group, a substituted or unsubstituted m-terphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, or a combination thereof, but are limited thereto.

As used herein, hole characteristics refers to characteristics related to how easily holes formed in the anode are injected into the emission layer and transported in the emission layer due to conductive characteristics according to the HOMO level. More specifically, it is similar to electron-repelling characteristics.

In addition, electron characteristics refers to characteristics related to how easily electrons formed in the cathode are injected into the emission layer and transported in the emission layer due to conductive characteristics according to the LUMO level. More specifically, it is similar to electron-withdrawing characteristics.

In one embodiment of the present invention, a compound represented by the following Chemical Formula 1 is provided.

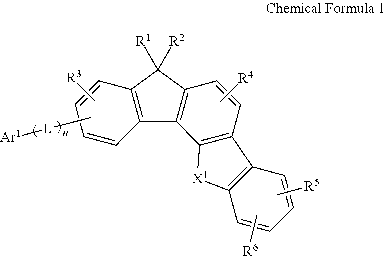

In the above Chemical Formula 1, X¹ is —O—, —S—, or —CR^{a}R^{b}—; Ar¹ is a substituted or unsubstituted C6 to C30 aryl group; R¹ and R² are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; or R¹ and R² may be fused with each other to form a ring; R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; L is a substituted or unsubstituted C6 to C30 arylene group; and n is an integer from 0 to 3.

In one embodiment, the compound for an organic optoelectronic device compound may be represented by the following Chemical Formula 2.

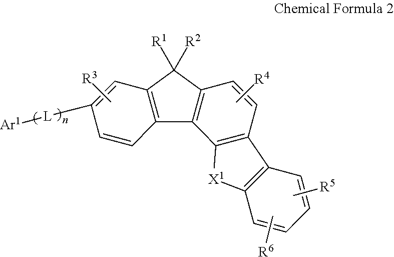

In the above Chemical Formula 2, X¹ is —O—, —S—, or —CR^{a}R^{b}—; Ar¹ is a substituted or unsubstituted C6 to C30 aryl group; R¹ and R² are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; or R¹ and R² are fused with each other to form a ring; R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; L is a substituted or unsubstituted C6 to C30 arylene group; and n is an integer from 0 to 3.

In one embodiment, the compound for an organic optoelectronic device compound may be represented by the following Chemical Formula 3.

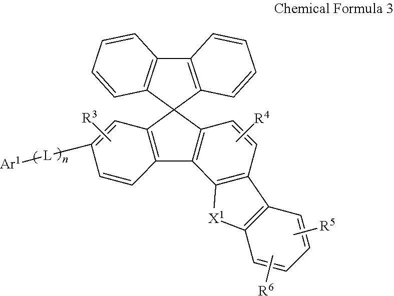

In the above Chemical Formula 3, X¹ is —O—, —S—, or —CR^{a}R^{b}—; Ar¹ is a substituted or unsubstituted C6 to C30 aryl group; R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; L is a substituted or unsubstituted C6 to C30 arylene group; and n is an integer from 0 to 3.

The compounds according to one embodiment of the present invention include condensation (condensed) compound cores as in the above Chemical Formulae 1 to 3 and thus have an improved (higher) glass transition temperature and crystallization (e.g., lower crystallinity).

The compounds represented by the above Chemical Formulae 1 to 3 include various substituents and thus may have various energy bandgaps.

The compound may have an appropriate energy level depending on the substituents and thus, may fortify (or improve) hole transport characteristics or electron transport characteristics of an organic optoelectronic device and bring about excellent effects on efficiency and driving voltage and also, have excellent electrochemical and thermal stability and thus, improve life-span characteristics during the operation of the organic optoelectronic device.

In one embodiment, Ar¹ may be a substituted or unsubstituted C6 to C30 aryl group.

In one embodiment, Ar¹ may be a substituted or unsubstituted phenyl group, a substituted or unsubstituted biphenyl group, a substituted or unsubstituted naphthyl group, a substituted or unsubstituted anthracenyl group, or a substituted or unsubstituted phenanthrenyl group.

In these cases, hole and/or electron characteristics of the compound may be appropriately adjusted.

In one embodiment, Ar¹ may be a silyl group, a cyano group, deuterium, a halogen, or a C6 to C30 aryl group substituted with a C1 to C10 alkyl group, but is not limited thereto.

In addition, L may be selectively adjusted to determine conjugation length of the compound, and thus, a triplet energy bandgap may be adjusted based on the adjustment of L.

Accordingly, characteristics of a material required in an organic optoelectronic device may be realized. In addition, the triplet energy bandgap may be adjusted by changing the bonding position to be ortho, para, or meta.

In one embodiment, L may be a substituted or unsubstituted C6 to C30 arylene group, and herein, the compound may have appropriate hole and electron characteristics.

In one embodiment, L may be a substituted or unsubstituted phenylene group, a substituted or unsubstituted biphenylene group, a substituted or unsubstituted terphenylene group, a substituted or unsubstituted naphthylene group, a substituted or unsubstituted anthracenylene group, a substituted or unsubstituted phenanthrylene group, a substituted or unsubstituted pyrenylene group, a substituted or unsubstituted fluorenylene group, a substituted or unsubstituted p-terphenyl group, a substituted or unsubstituted m-terphenyl group, a substituted or unsubstituted perylenyl group, or the like.

In one embodiment, L may be represented by the following Chemical Formulae 4 to 9, but is not limited thereto. In the following chemical formulae, * indicates a linking position.

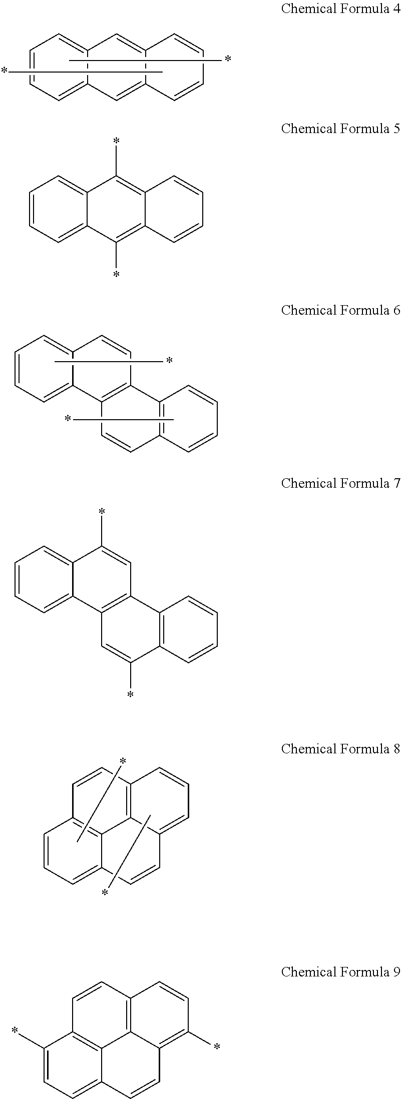

X¹ may be —S—, but is not limited thereto.

Examples of the compounds according to one embodiment are as follows, but are not limited thereto.

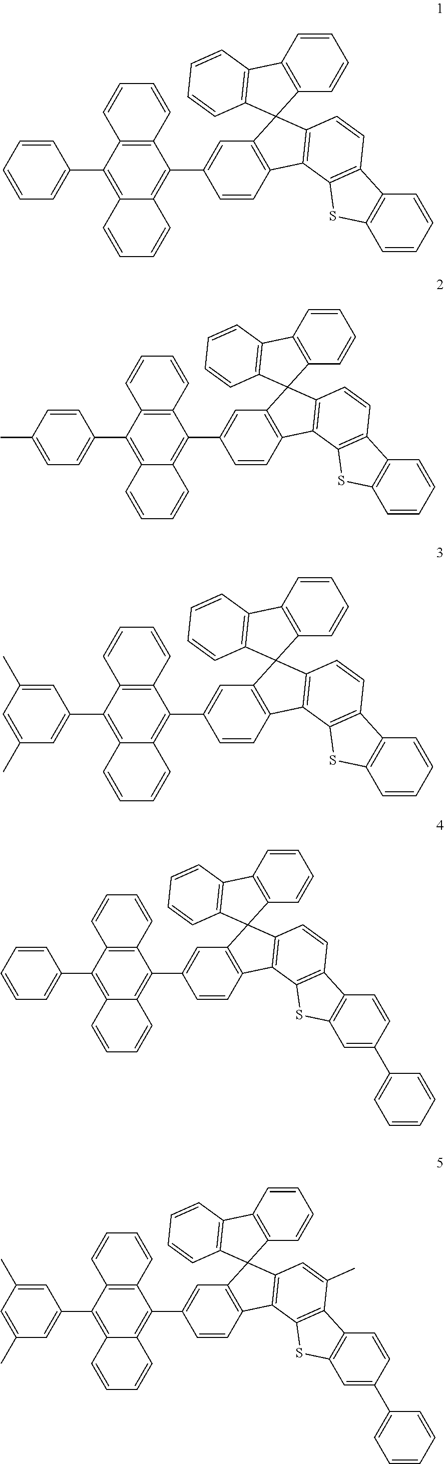 [SMILES: c1ccc(-c2c3ccccc3c(-c3ccc4c(c3)C3(c5ccccc5-c5ccccc53)c3ccc5c(sc6ccccc65)c3-4)c3ccccc23)cc1 ; Cc1ccc(-c2c3ccccc3c(-c3ccc4c(c3)C3(c5ccccc5-c5ccccc53)c3ccc5c(sc6ccccc65)c3-4)c3ccccc23)cc1 ; Cc1cc(C)cc(-c2c3ccccc3c(-c3ccc4c(c3)C3(c5ccccc5-c5ccccc53)c3ccc5c(sc6ccccc65)c3-4)c3ccccc23)c1 ; c1ccc(-c2ccc3c(c2)sc2c4c(ccc23)C2(c3ccccc3-c3ccccc32)c2cc(-c3c5ccccc5c(-c5ccccc5)c5ccccc35)ccc2-4)cc1 ; Cc1cc(C)cc(-c2c3ccccc3c(-c3ccc4c(c3)C3(c5ccccc5-c5ccccc53)c3cc(C)c5c(sc6cc(-c7ccccc7)ccc65)c3-4)c3ccccc23)c1]

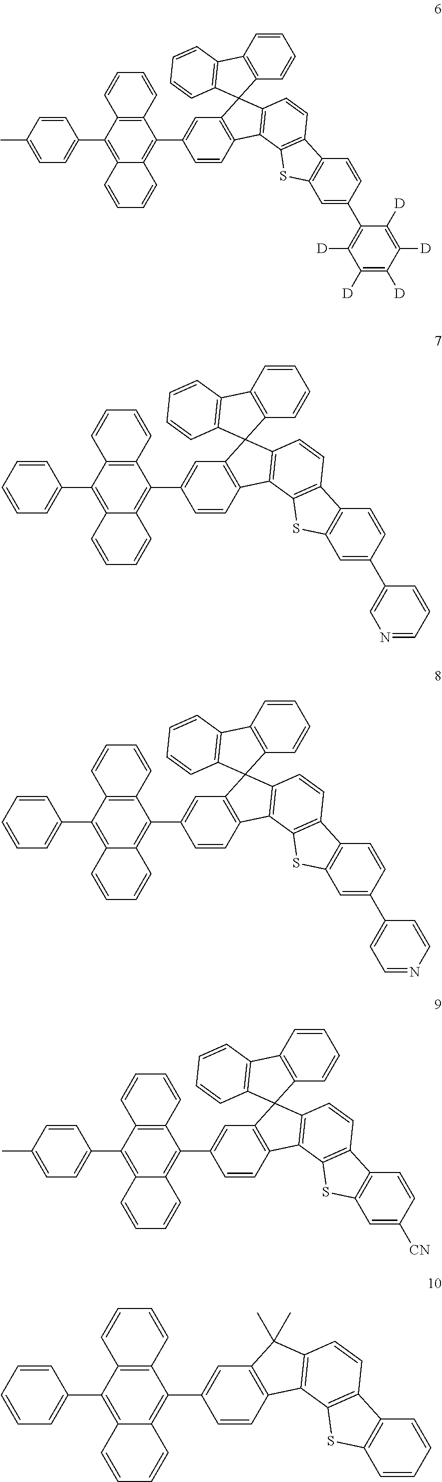

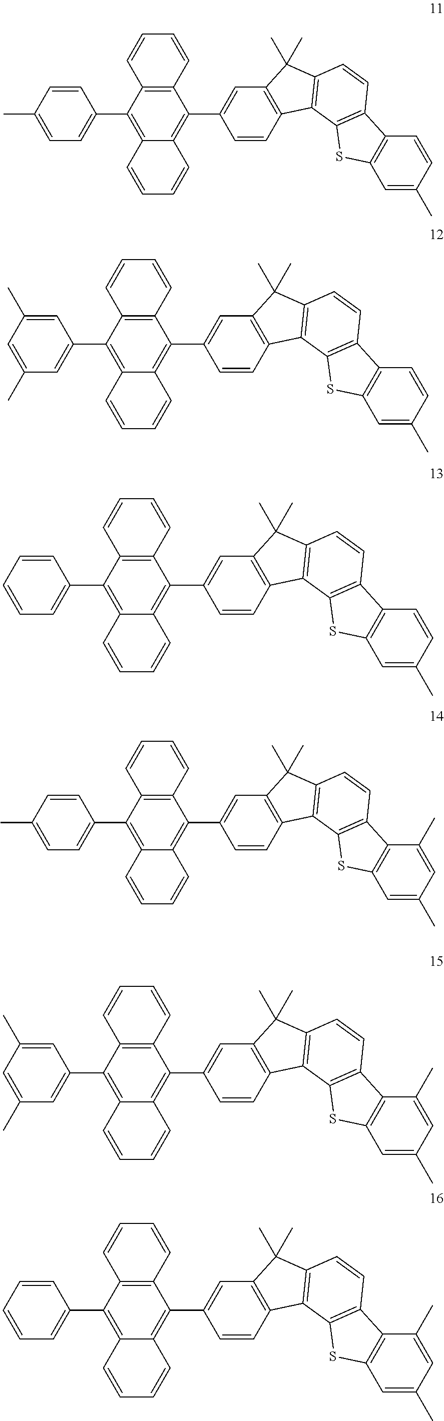

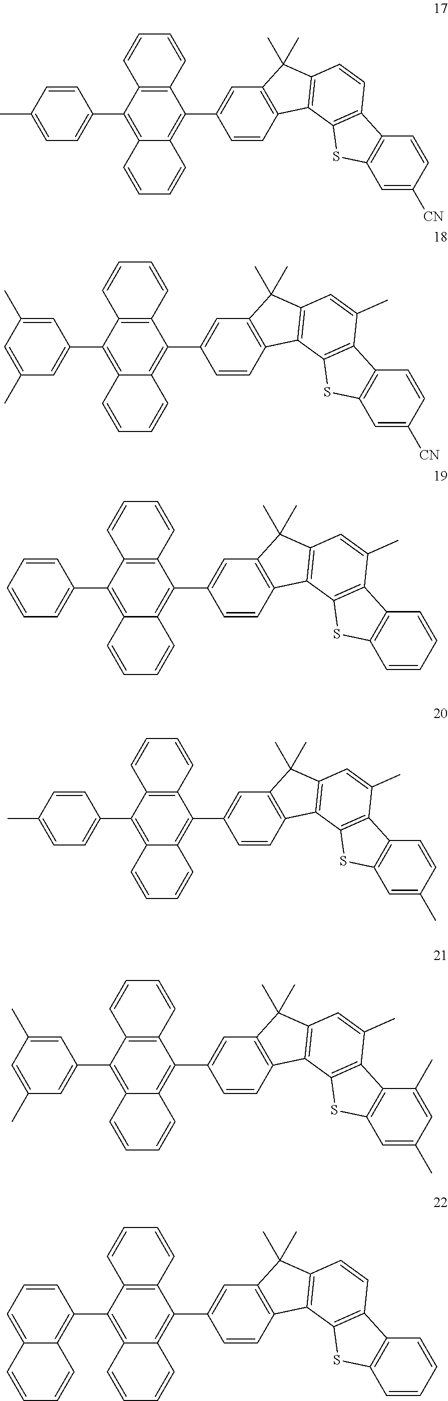

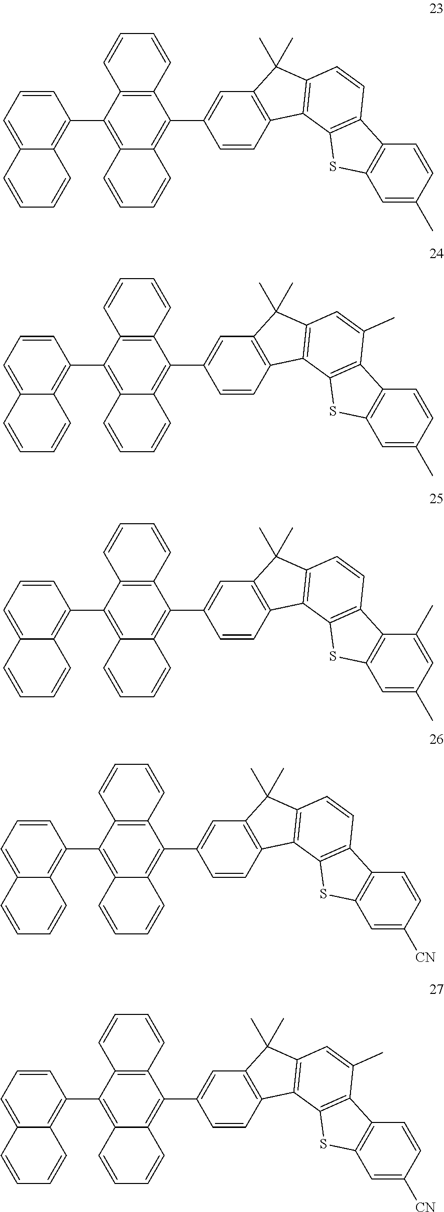 [SMILES: Cc1ccc2c(c1)sc1c3c(ccc12)C(C)(C)c1cc(-c2c4ccccc4c(-c4cccc5ccccc45)c4ccccc24)ccc1-3 ; Cc1ccc2c(c1)sc1c3c(cc(C)c12)C(C)(C)c1cc(-c2c4ccccc4c(-c4cccc5ccccc45)c4ccccc24)ccc1-3 ; Cc1cc(C)c2c(c1)sc1c3c(ccc12)C(C)(C)c1cc(-c2c4ccccc4c(-c4cccc5ccccc45)c4ccccc24)ccc1-3 ; CC1(C)c2cc(-c3c4ccccc4c(-c4cccc5ccccc45)c4ccccc34)ccc2-c2c1ccc1c2sc2cc(C#N)ccc21 ; Cc1cc2c(c3sc4cc(C#N)ccc4c13)-c1ccc(-c3c4ccccc4c(-c4cccc5ccccc45)c4ccccc34)cc1C2(C)C]

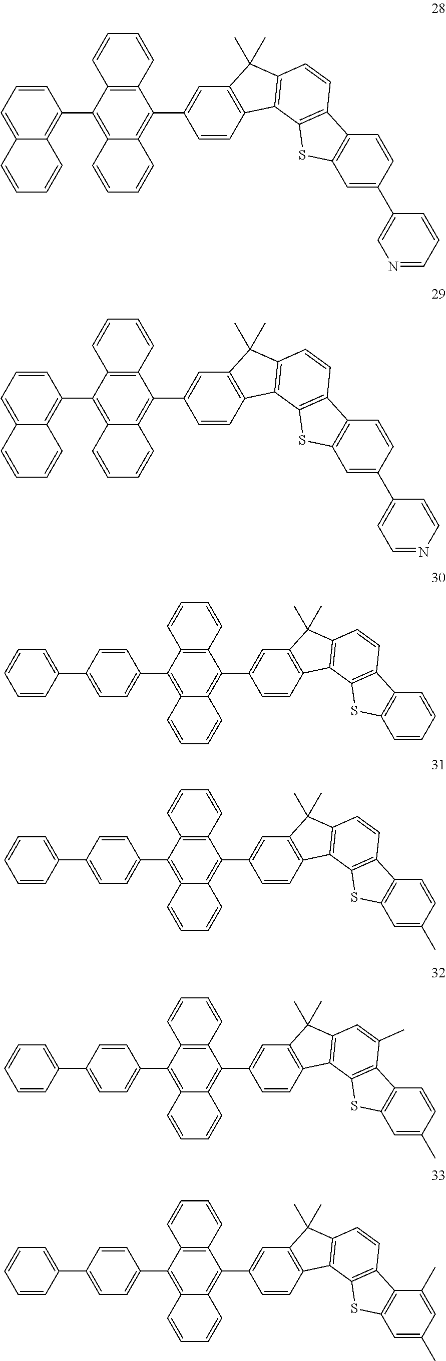

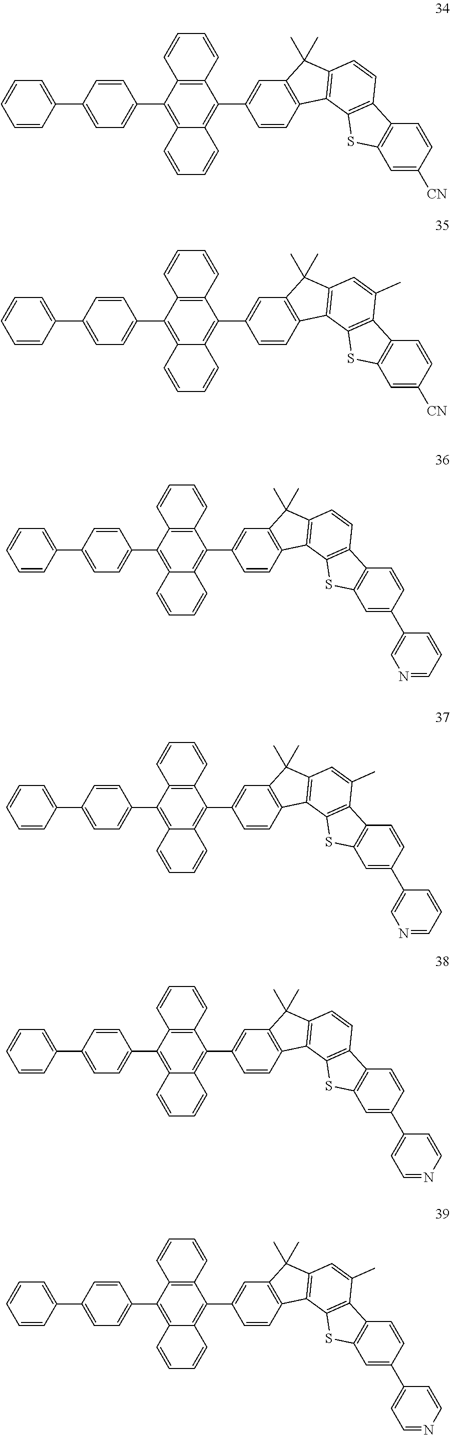

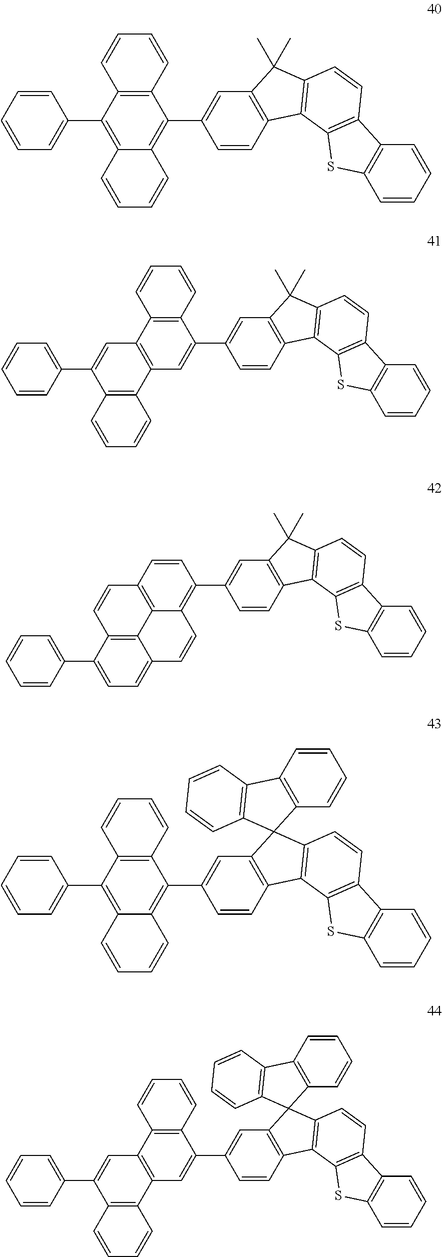 [SMILES: CC1(C)c2cc(-c3c4ccccc4c(-c4ccccc4)c4ccccc34)ccc2-c2c1ccc1c2sc2ccccc21 ; CC1(C)c2cc(-c3cc4c5ccccc5c(-c5ccccc5)cc4c4ccccc34)ccc2-c2c1ccc1c2sc2ccccc21 ; CC1(C)c2cc(-c3ccc4ccc5c(-c6ccccc6)ccc6ccc3c4c65)ccc2-c2c1ccc1c2sc2ccccc21 ; c1ccc(-c2c3ccccc3c(-c3ccc4c(c3)C3(c5ccccc5-c5ccccc53)c3ccc5c(sc6ccccc65)c3-4)c3ccccc23)cc1 ; c1ccc(-c2cc3c4ccccc4c(-c4ccc5c(c4)C4(c6ccccc6-c6ccccc64)c4ccc6c(sc7ccccc76)c4-5)cc3c3ccccc23)cc1]

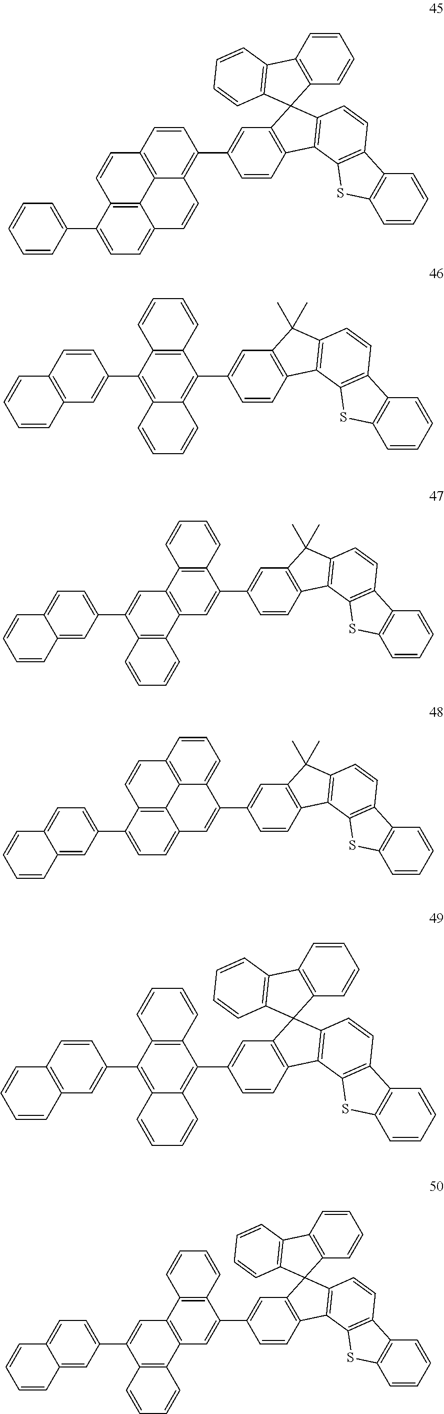

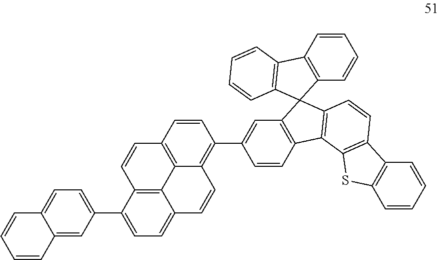 [SMILES: c1ccc2c(c1)-c1ccccc1C21c2cc(-c3ccc4ccc5c(-c6ccc7ccccc7c6)ccc6ccc3c4c65)ccc2-c2c1ccc1c2sc2ccccc21]

In another embodiment of the present invention, an organic light emitting diode includes an anode, a cathode, and at least one of an organic thin layer interposed between the anode and cathode, wherein the at least one of the organic thin layer includes the above compound according to one embodiment of the present invention.

The compound for an organic optoelectronic device is used in an organic thin layer and thus improves life-span characteristics, efficiency, electrochemical stability, and thermal stability of the organic optoelectronic device, and lowers a driving voltage.

The organic thin layer may be (e.g., specifically) an emission layer.

The organic optoelectronic device may be an organic light emitting diode, an organic photoelectric device, an organic solar cell, an organic transistor, an organic photo-conductor drum, or an organic memory device.

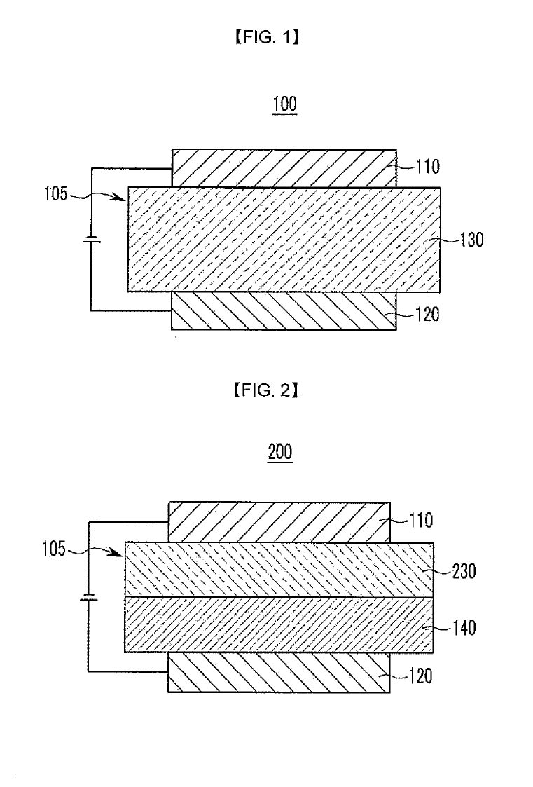

More specifically (i.e., for example), the organic optoelectronic device may be an organic light emitting diode. FIGS. 1 to 5 are cross-sectional views showing organic light emitting diodes including the compound for an organic optoelectronic device according to various embodiments of the present invention.

Referring to FIGS. 1 to 5, organic light emitting diodes 100, 200, 300, 400, and 500 according to various embodiments of the present invention include at least one organic thin layer 105 interposed between an anode 120 and a cathode 110.

The anode 120 includes an anode material having a large work function to help hole injection into an organic thin layer. The anode material includes: a metal such as nickel, platinum, vanadium, chromium, copper, zinc, or gold, or alloys thereof; a metal oxide such as zinc oxide, indium oxide, indium tin oxide (ITO), or indium zinc oxide (IZO); a bonded metal and oxide composite such as ZnO:Al or SnO₂:Sb; or a conductive polymer such as poly(3-methylthiophene), poly[3,4-(ethylene-1,2-dioxy)thiophene] (PEDT), polypyrrole, or polyaniline, but is not limited thereto. In one embodiment, a transparent electrode including indium tin oxide (ITO) is used as an anode.

The cathode 110 includes a cathode material having a small work function to help electron injection into an organic thin layer. The cathode material includes: a metal such as magnesium, calcium, sodium, potassium, titanium, indium, yttrium, lithium, gadolinium, aluminum, silver, tin, or lead, or alloys thereof; or a multi-layered material such as LiF/Al, Liq/Al, LiO₂/Al, LiF/Ca, LiF/Al, or BaF₂/Ca, but is not limited thereto. In one embodiment, a metal electrode including aluminum is used as a cathode.

Referring to FIG. 1, the organic light emitting diode 100 includes an organic thin layer 105 including only an emission layer 130.

Referring to FIG. 2, a double-layered organic light emitting diode 200 includes an organic thin layer 105 including an emission layer 230, which includes an electron transport layer (ETL), and a hole transport layer (HTL) 140. As shown in FIG. 2, the organic thin layer 105 includes a double layer of the emission layer 230 and the hole transport layer (HTL) 140. The emission layer 130 (or 230 in this embodiment) also functions as an electron transport layer (ETL), and the hole transport layer (HTL) 140 layer has an excellent binding property with a transparent electrode such as ITO or an excellent hole transport capability.

Referring to FIG. 3, a three-layered organic light emitting diode 300 includes an organic thin layer 105 including an electron transport layer (ETL) 150, an emission layer 130, and a hole transport layer (HTL) 140. The emission layer 130 is independently installed, and layers having an excellent electron transport capability or an excellent hole transport capability are separately stacked.

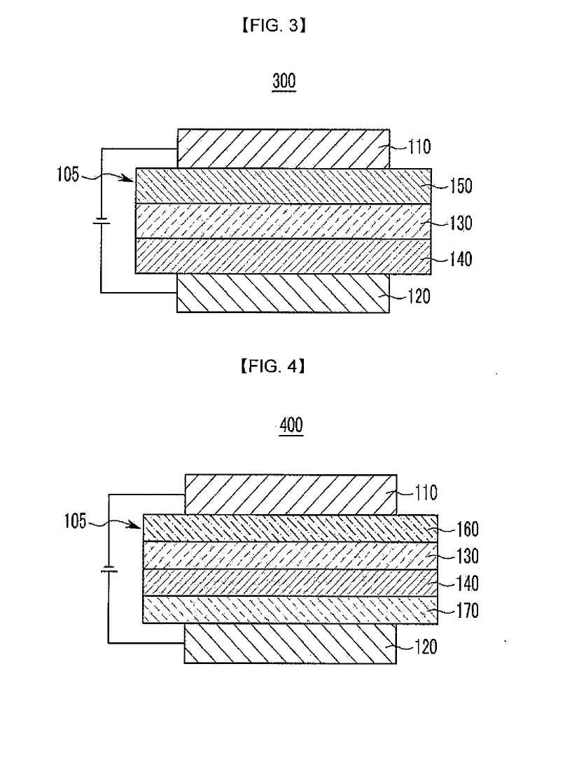

As shown in FIG. 4, a four-layered organic light emitting diode 400 includes an organic thin layer 105 including an electron injection layer (EIL) 160, an emission layer 130, a hole transport layer (HTL) 140, and a hole injection layer (HIL) 170 for adherence with the cathode of ITO.

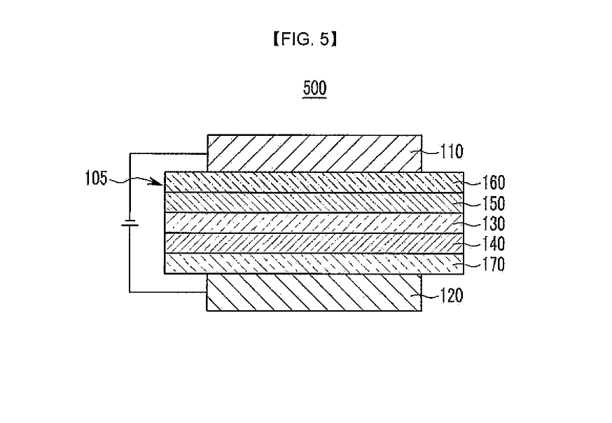

As shown in FIG. 5, a five layered organic light emitting diode 500 includes an organic thin layer 105 including an electron transport layer (ETL) 150, an emission layer 130, a hole transport layer (HTL) 140, and a hole injection layer (HIL) 170, and further includes an electron injection layer (EIL) 160 to achieve a low driving voltage.

In FIGS. 1 to 5, the organic thin layer 105 includes at least one selected from an electron transport layer (ETL) 150, an electron injection layer (EIL) 160, emission layers 130 or 230, a hole transport layer (HTL) 140, a hole injection layer (HIL) 170, or combinations thereof. The organic thin layer 105 includes a compound represented by Formula 1 for an organic optoelectronic device.

Particularly, the compound may be used in the emission layers 130 and 230, and may be used as a green phosphorescent dopant material in the emission layers.

The organic light emitting diode may be manufactured by: forming an anode on a substrate; forming an organic thin layer; and providing a cathode thereon. The organic thin layer may be formed in accordance with a dry coating method such as evaporation, sputtering, plasma plating, or ion plating; or a wet coating method such as spin coating, dipping, or flow coating.

Another embodiment of the present invention provides a display device including the organic photoelectric device according to the above embodiment.

Hereinafter, the embodiments are illustrated in more detail with reference to examples. However, these examples are exemplary, and the present disclosure is not limited thereto.

### (Preparation of Compound for Organic Optoelectronic Device)

### SYNTHESIS EXAMPLE 1

### Synthesis of Compound 1

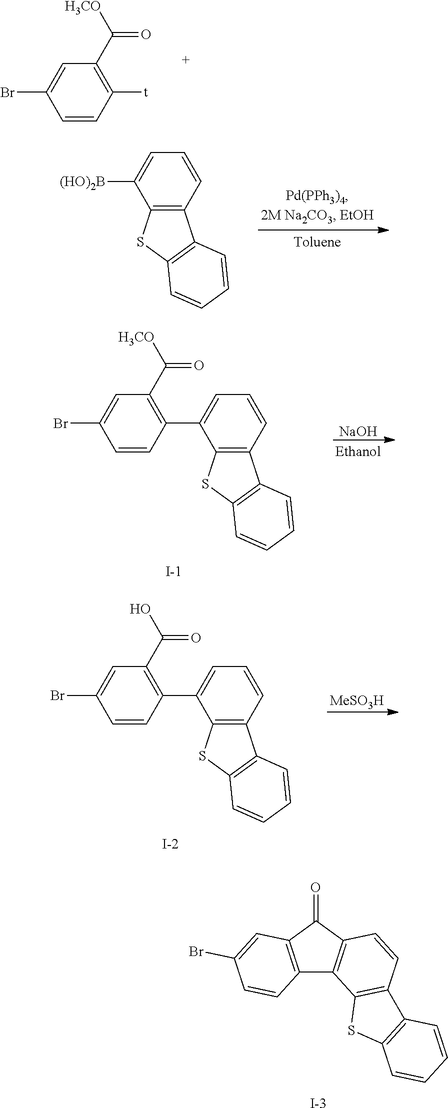

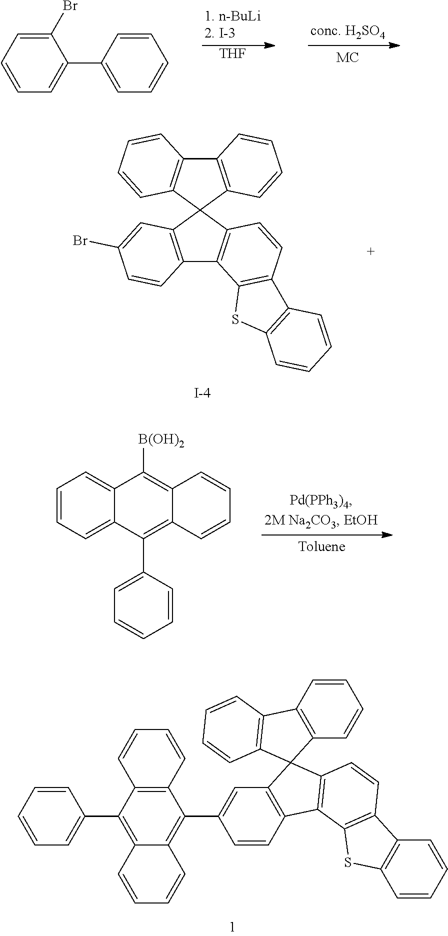

### Synthesis of Intermediate I-1

3 g (1 eq, 8.80 mmol) of methyl 5-bromo-2-iodobenzoate, 2.21 g (1.1 eq, 9.68 mmol of dibenzo[b,d]thiophen-4-ylboronic acid, and 410 mg (0.04 eq, 0.35 mmol) of tetrakis(triphenylphosphine)palladium (0) were put in a reaction vessel, and then vacuum-dried followed by filling a nitrogen gas. 70 ml of toluene was added to the flask to dissolve the compounds, 30 ml of ethanol and 13 ml (3 eq, 26.4 mmol) of a 2.0 M sodium carbonate aqueous solution were added thereto, and refluxed at 120° C. for 3 hours followed by agitating the same. After completing the reaction, the resultant was washed with distilled water and an organic layer was extracted with ethyl acetate. The resultant was dried with magnesium sulfate, filtered, and the solvent was evaporated. Through column chromatography. 3.5 g (yield=75%) of an intermediate I-1 (methyl 5-bromo-2-(dibenzo[b,d]thiophen-4-yl)benzoate) was obtained.

1H-NMR: 8.18 (m, 3H), 7.76 (t, 2H), 7.53 (t, 1H), 7.45 (m, 2H), 7.38 (d, 1H), 7.27 (d, 1H), 3.55 (s, 3H). APCI-MS (m/z): 397[M⁺]

### Synthesis of Intermediate I-2

3.5 g (1 eq, 8.81 mmol) of the intermediate I-1 was added to a reaction vessel and 50 ml of ethyl alcohol was added. 1.06 g (3 eq, 26.43 mmol) of sodium hydroxide was added and then refluxed at 90° C. for 3 hours followed by agitating the same. Then, hydrochloride (concentration) was slowly added in a dropwise fashion. After completing the reaction, the resultant was extracted with ethyl ether and dried to obtain 3 g (yield=89%) of an intermediate I-2 (5-bromo-2-(dibenzo[b,d]thiophen-4-yl)benzoic acid).

1H-NMR: 8.17 (m, 3H), 7.76 (d, 2H), 7.47 (m, 3H), 7.36 (d, 1H), 7.22 (d, 1H). APCI-MS (m/z): 383[M+]

### Synthesis of Intermediate I-3

100 ml of MeSO₃H (methane sulfonic acid) was added to a vessel including 3 g (1 eq, 7,82 mmol) of the intermediate I-2 and then agitated at 30° C. for 6 hours. After completing the reaction, the reaction solution was poured into a beaker including ice, the resultant was agitated and filtered, then the solid product was washed with NaHCO₃ (sodium bicarbonate) aqueous solution again, and agitated and filtered to obtain 2.6 g (yield=90%) of an intermediate I-3 (9-bromo-7H-benzo[b]fluoreno[3,4-d]thiophen-7-one).

1H-NMR: 8.20 (d, 1H), 8.16 (d, 1H), 7.94 (d, 1H), 7.80 (s, 1H), 7.79 (d, 1H), 7.70 (d, 1H), 7.58 (m, 3H). APCI-MS (m/z): 365[M+]

### Synthesis of Intermediate I-4

1.74 g (1.05 eq, 7.47 mmol) of 2-bromobiphenyl was added to a flask and dissolved by adding 150 ml of THF. 4.67 ml (1.05 eq, 7.47 mmol) of n-BuLi (1.6 M) was added in a dropwise fashion at −78° C. After agitating the same for 30 minutes, 2.6 g (1 eq, 7.11 mmol) of the intermediate I-3 was added. The resultant was agitated at room temperature for 5 hours. After completing the reaction, the resultant was washed with distilled water and extracted with ethyl acetate, a solvent was dried, then the resultant was added to a reaction vessel, and was dissolved in MC and sulfuric acid (H₂SO₄) was slowly added in a dropwise fashion. The reaction solution was extracted with dichloromethane, and 2.1 g (yield=60%) of an intermediate I-4 (9-bromospiro[benzo[b]fluoreno[3,4-d]thiophene-7,9′-fluorene]) was obtained by column chromatography.

1H-NMR: 8.16 (d, 1H), 7.90 (m, 5H), 7.64 (d, 1H), 7.51 (m, 2H), 7.42 (t, 2H), 7.12 (t, 2H), 6.94 (s, 1H), 6.84 (d, 1H), 6.78 (d, 2H). APCI-MS (m/z): 501[M+]

### Synthesis of Compound 1

2.1 g (1 eq, 4.19 mmol) of the intermediate I-4 and 1.59 g (1.03 eq, 4.34 mmol) of 9-phenylanthracen-10-ylboronic acid, and 200 mg (0.04 eq, 0.17 mmol) of tetrakis(triphenylphosphine)palladium (0) were put in a reaction vessel and vacuum-dried followed by filling a nitrogen gas. 60 nil of toluene was added to the flask to dissolve the compounds, then 30 ml of ethanol and 6.4 ml (3 eq, 12.57 mmol) of a 2.0 M sodium carbonate aqueous solution was added, and then agitated at 120° C. for 3 hours while refluxing the same. After completing the reaction, the resultant was washed with distilled water and an organic layer was extracted with ethyl acetate. The resultant was dried with magnesium sulfate, filtered through Celite and then through column chromatography. 1.72 g (yield=61%) of compound 1, (9-(10-phenylanthracen-9-yl)spiro[benzo[d]fluoreno[4,3-b]thiophene-7,9′-fluorene]) was obtained.

1H-NMR: 8.31 (d, 1H), 8.20 (d, 1H), 8.05 (m, 2H), 7.77 (d, 2H), 7.65 (t, 4H), 7.60 (m, 3H), 7.53 (m, 3H), 7.46 (t, 2H), 7.33 (t, 4H), 7.27 (d, 2H), 7.15 (t, 2H), 6.95 (m, 4H). APCI-MS (m/z): 675[M+]

### SYNTHESIS EXAMPLE 2

### Synthesis of Compound 10

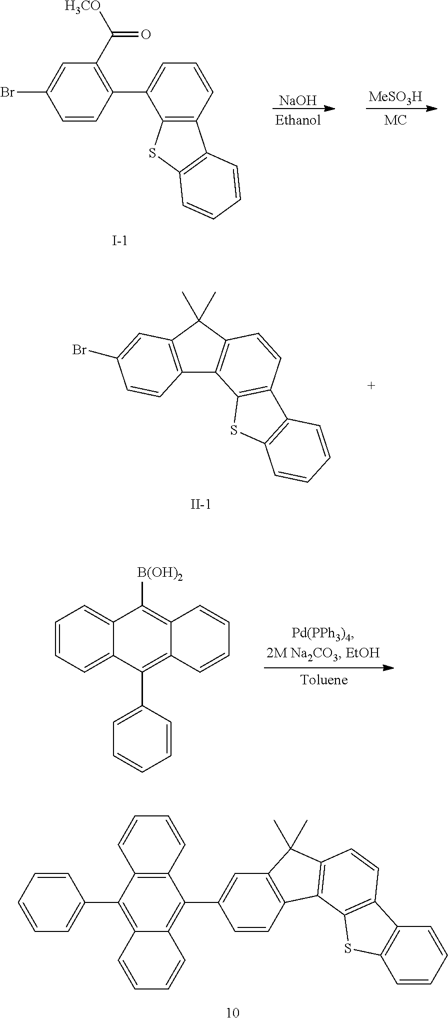

### Synthesis of Intermediate II-1

6 g (1 eq, 15.1 mmol) of the intermediate I-1 was added to a reaction vessel and then vacuum-dried followed by filling a nitrogen gas. 120 ml of THF was added. 12.5 ml (2.5 eq, 37.7 mmol) of methyl magnesium chloride (3.0 M) was slowly added in a dropwise fashion. The reaction solution was extracted with ethyl acetate, reactants was put in a flask and was dissolved in MC, and MeSO₃H (methane sulfonic acid) was added in a dropwise fashion. After completing the reaction, the resultant was extracted with dichloromethane, and 4 g (yield=70%) of an intermediate II-1 (9-bromo-7,7-dimethyl-7H-benzo[b]fluoreno[3,4-d]thiophene) was obtained through column chromatography.

1H-NMR: 8.22 (d, 1H), 8.19 (d, 1H), 7.96 (d, 1H), 7.82 (d, 1H), 7.64 (t, 2H), 7.56 (d, 1H), 7.51 (m, 2H), 1.57 (s, 6H). APCI-MS (m/z): 379[M+]

### Synthesis of Compound 10

4 g (1 eq, 10.5 mmol) of the intermediate II-1 and 3.23 g (1.03 eq, 10.86 mmol) of 9-phenylanthracen-10-yl boronic acid, and 485 mg (0.04 eq, 0.42 mmol) of tetrakis(triphenylphosphine)palladium (0) were put in a reaction vessel, and then vacuum-dried followed by filling a nitrogen gas. 80 ml of toluene was added to the flask to dissolve the compounds, 40 ml of ethanol and 16 ml (3 eq, 31.5 mmol) of a 2.0 M sodium carbonate aqueous solution were added thereto, and refluxed at 120° C. for 3 hours followed by agitating the same. After completing the reaction, the resultant was washed with distilled water and an organic layer was extracted with ethyl acetate. The resultant was dried with magnesium sulfate, filtered through Celite and then through column chromatography. 4 g (yield=70%) of a compound 10 (7,7-dimethyl-9-(10-phenylanthracen-9-yl)-7H-benzo[d]fluoreno[4,3-b]thiophene) was obtained.

1H-NMR: 8.28 (d, 1H), 8.22 (t, 2H), 8.01 (d, 1H), 7.82 (d, 2H), 7.74 (t, 2H), 7.60 (m, 10H), 7.36 (m, 4H), 1.64 (s, 6H). APCI-MS (m/z): 553[M+]

### SYNTHESIS EXAMPLE 3

### Synthesis of Compound 22

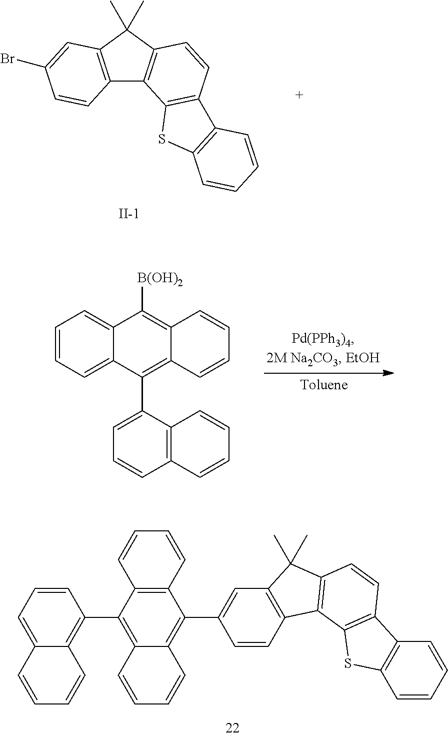 [SMILES: CC1(C)c2cc(Br)ccc2-c2c1ccc1c2sc2ccccc21 ; "II-1" ; OB(O)c1c2ccccc2c(-c2cccc3ccccc23)c2ccccc12 ; CC1(C)c2cc(-c3c4ccccc4c(-c4cccc5ccccc45)c4ccccc34)ccc2-c2c1ccc1c2sc2ccccc21]

### Synthesis of Compound 22

4 g (1 eq, 10.5 mmol) of the intermediate II-1, 3.85 g (1.05 eq, 11.03 mmol) of 10-(naphthalen-1-yl)anthracen-9-ylboronic acid, and 485 mg (0.04 eq, 0.42 mmol) of tetrakis(triphenylphosphine)palladium (0) were put in a reaction vessel and then vacuum-dried followed by filling a nitrogen gas. 80 ml of toluene was added to the flask to dissolve the compounds, 40 ml of ethanol and 16 ml (3 eq, 31.6 mmol) of a 2.0 M sodium carbonate aqueous solution were added thereto, and refluxed at 120° C. for 3 hours followed by agitating the same. After completing the reaction, the resultant was washed with distilled water and an organic layer was extracted with ethyl acetate. The resultant was dried with magnesium sulfate, filtered through Celite and then through column chromatography. 4.4 g (yield=70%) of a compound 22 (7,7-dimethyl-9-(10-(naphthalen-1-yl)anthracen-9-yl)-7H-benzo[d]fluoreno[4,3-b]thiophene) was obtained.

1H-NMR: 8.25 (m, 3H), 8.08 (m, 3H), 7.95 (d, 1H), 7.88 (d, 2H), 7.76 (t, 3H), 7.67 (t, 2H), 7.60 (t, 2H), 7.50 (m, 6H), 7.36 (m 2H), 1.70 (s, 6H). APCI-MS (m/z): 603[M+]

### SYNTHESIS EXAMPLE 4

### Synthesis of Compound 30

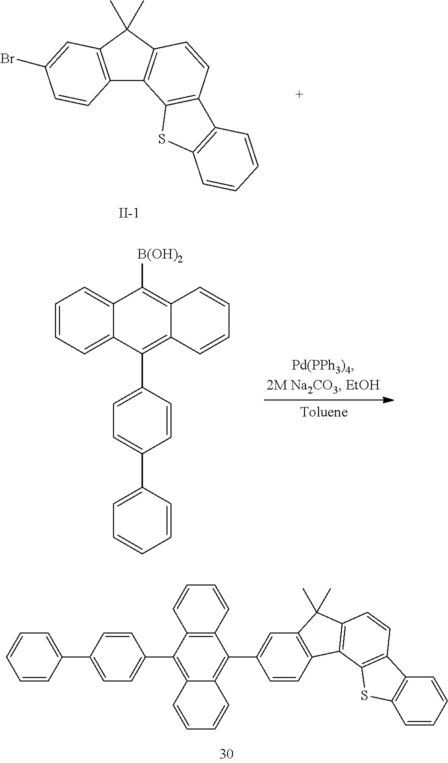 [SMILES: CC1(C)c2cc(Br)ccc2-c2c1ccc1c2sc2ccccc21 ; "II-1" ; OB(O)c1c2ccccc2c(-c2ccc(-c3ccccc3)cc2)c2ccccc12 ; CC1(C)c2cc(-c3c4ccccc4c(-c4ccc(-c5ccccc5)cc4)c4ccccc34)ccc2-c2c1ccc1c2sc2ccccc21]

### Synthesis of Compound 30

4 g (1 eq, 10.5 mmol) of the intermediate II-1, 4.12 g (1.05 eq, 11.07 mmol) of 10-(biphenyl-4-yl)anthracen-9-ylboronic acid, and 485 mg (0.04 eq, 0.42 mmol) of tetrakis(triphenylphosphine)palladium (0) tetrakis(triphenylphosphine)palladium (0). 80 ml of toluene was added to the flask to dissolve the compounds, 40 ml of ethanol and 16 ml (3 eq, 31.6 mmol) of a 2.0 M sodium carbonate aqueous solution were added thereto, and refluxed at 120° C. for 3 hours followed by agitating the same. After completing the reaction, the resultant was washed with distilled water and an organic layer was extracted with ethyl acetate. The resultant was dried with magnesium sulfate, filtered through Celite and then through column chromatography. 4.32 g (yield=65%) of a compound 30 (9-(10-(biphenyl-4-yl)anthracen-9-yl)-7,7-dimethyl-7H-benzo[d]fluoreno[4,3-b]thiophene) was obtained.

1H-NMR: 8.25 (m, 3H), 8.01 (d, 1H), 7.847 (m, 9H), 7.60 (m, 9H), 7.40 (m, 4H), 1.61 (s, 5H), 1.53 (s, 1H). APCI-MS (m/z): 629[M+]

### SYNTHESIS EXAMPLE 5

### Synthesis of Compound 2

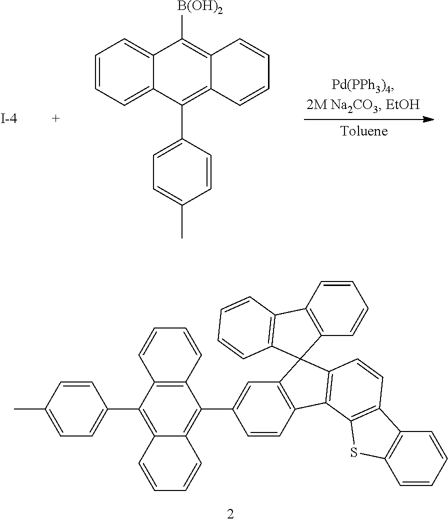

### Synthesis of Compound 2

2.1 g (1 eq, 4.19 mmol) of the intermediate I-4, 1.35 g (1.03 eq, 4.34 mmol) of (10-(p-tolyl)anthracen-9-yl)boronic acid, and 200 mg (0.04 eq, 0.17 mmol) of tetrakis(triphenylphosphine)palladium (0) were put in a reaction vessel, and then vacuum-dried followed by filling a nitrogen gas. 60 ml of toluene was added to the flask to dissolve the compounds, 30 ml of ethanol and 6.4 ml (3 eq, 12.57 mmol) of a 2.0 M sodium carbonate aqueous solution were added thereto, and refluxed at 120° C. for 3 hours followed by agitating the same. After completing the reaction, the resultant was washed with distilled water and an organic layer was extracted with ethyl acetate. The resultant was dried with magnesium sulfate, filtered through Celite and then through column chromatography. 1.54 g (yield=53%) of a compound 2(9-(10-(p-tolyl)anthracen-9-yl)spiro[benzo[b]fluoreno[3,4-d]thiophene-7,9′-fluorene]) was obtained.

1H-NMR: 8.43 (1H, d), 8.12 (2H, m), 8.06 (2H, d), 7.96 (3H, m), 7.90 (2H, m), 7.64 (2H, d), 7.52 (16H, m), 5.54 (1H, s), 2.44 (3H, s). APCI-MS (m/z): 689[M+]

### SYNTHESIS EXAMPLE 6

### Synthesis of Compound 45

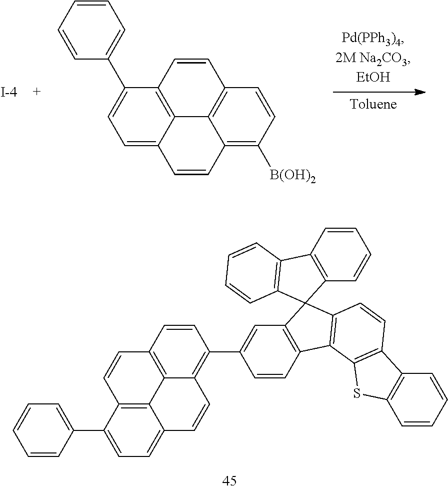

### Synthesis of Compound 45

2.1 g (1 eq, 4.19 mmol) of the intermediate I-4, 1.39 g (1.03 eq, 4.34 mmol) of (6-phenylpyren-1-yl)boronic acid, and 200 mg (0.04 eq, 0.17 mmol) of tetrakis(triphenylphosphine)palladium (0) were put in a reaction vessel, and then vacuum-dried followed by filling a nitrogen gas. 60 ml of toluene was added to the flask to dissolve the compounds, 30 ml of ethanol and 6.4 ml (3 eq, 12.57 mmol) of a 2.0 M sodium carbonate aqueous solution were added thereto, and refluxed at 120° C. for 3 hours followed by agitating the same. After completing the reaction, the resultant was washed with distilled water and an organic layer was extracted with ethyl acetate. The resultant was dried with magnesium sulfate, filtered through Celite and then through column chromatography. 1.85 g (yield=63%) of a compound 45 (9-(6-phenylpyren-1-yl)spiro[benzo[b]fluoreno[3,4-d]thiophene-7,9′-fluorene]) was obtained.

1H-NMR: 8.54 (1H, d), 8.39 (1H, m), 8.23 (4H, m), 8.09 (2H, m), 8.03 (6H, m), 7.88 (2H, m), 7.69 (2H, m), 7.54 (5H, m), 7.45 (7H, m). APCI-MS (m/z): 699[M+]

### (Manufacture of Organic Light Emitting Diode)

### EXAMPLE 1

An anode was manufactured by cutting a 15 Ω/cm² (1200 Å) ITO glass substrate (Corning Inc.) into a size of 50 mm×50 mm×0.7 mm, ultrasonic wave-washing it with isopropyl alcohol and pure water respectively, each for 5 minutes, radiating an ultraviolet (UV) ray for 30 minutes, cleaning it by exposing it to ozone, and then, mounting this glass substrate in a vacuum deposition apparatus.

On the substrate, 2-TNATA was vacuum-deposited to form a 600 Å-thick hole injection layer (HIL), and subsequently, a hole transport material, 4,4′-bis[N-(1-naphthyl)-N-phenylamino]biphenyl (hereinafter, NPB) as a hole transporting compound was vacuum-deposited to be a 300 Å-thick hole transport layer (HTL).

On the hole transport layer (HTL), compound 1 as a blue fluorescent host and 4,4′-bis[2-(4-(N,N-diphenylamino)phenyl)vinyl]biphenyl (hereinafter, DPAVBi) as a blue fluorescent dopant were simultaneously deposited in a weight ratio of 98:2 to form a 300 Å-thick emission layer.

Subsequently, Alq3 was deposited to form a 300 Å-thick electron transport layer (ETL) on (the upper side of) the emission layer; a halgenated alkaline metal, LiF, was deposited to form a 10 Å-thick electron injection layer (EIL) on the electron transport layer (ETL); and Al was vacuum-deposited to form a 3000 Å-thick LiF/Al electrode (a cathode), completing the manufacturing of an organic light emitting diode.

### EXAMPLE 2

An organic light emitting diode was manufactured according to the same method as Example 1 except for using compound 2 to form an emission layer instead of compound 1.

### EXAMPLE 3

An organic light emitting diode was manufactured according to the same method as Example 1 except for using compound 10 to form an emission layer instead of compound 1.

### EXAMPLE 4

An organic light emitting diode was manufactured according to the same method as Example 1 except for using compound 18 to form an emission layer instead of compound 1.

### EXAMPLE 5

An organic light emitting diode was manufactured according to the same method as Example 1 except for using compound 22 to form an emission layer instead of compound 1.

### EXAMPLE 6

An organic light emitting diode was manufactured according to the same method as Example 1 except for using compound 27 to form an emission layer instead of compound 1.

### EXAMPLE 7

An organic light emitting diode was manufactured according to the same method as Example 1 except for using compound 30 to form an emission layer instead of compound 1.

### EXAMPLE 8

An organic light emitting diode was manufactured according to the same method as Example 1 except for using compound 48 to form an emission layer instead of compound 1.

### COMPARATIVE EXAMPLE 1

An organic light emitting diode was manufactured according to the same method as Example 1 except for using 9,10-di-naphthalene-2-yl-anthracene (hereinafter, DNA) as a blue fluorescent host to form an emission layer instead of compound 1

### (Performance Measurement of Organic Light Emitting Diode)

Current density, luminance, efficiency, and life-span depending on (versus, or as a function of) voltage, and luminous efficiency of each organic light emitting diode according to Examples 1 to 8 and Comparative Example 1 were measured. The measurements were specifically performed in the following method. The results are shown in the following Table 1.

1) Measurement of Current Density vs. Voltage

The manufactured organic light emitting diodes were measured for current value flowing in the unit device, while increasing the voltage using a current-voltage meter (Keithley 2400), and the measured current value was divided by an area of the device to provide the result.

2) Measurement of Luminance vs. Voltage

The organic light emitting diodes were measured for luminance, while increasing the voltage using a luminance meter (Minolta Cs-1000A).

3) Measurement of Luminous Efficiency and Electric Power Efficiency

Luminous efficiency and electric power efficiency calculated by using the luminance, current density, and voltage (V) that are measured in “1) Measurement of Current density vs. Voltage” and “2) Measurement of Luminance vs. Voltage”, and the results are shown in Table 1.

4) Measurement of Life-Span

The decrease in luminance as a function of time (i.e., time lapse) of the organic light emitting diodes were measured using a Polaronix life-span measurement system, and then half-life life-spans were considered to be the time when the luminance became ½ of the initial luminance.

TABLE 1

| | Light | Driving | Current | | | Light | Half-life |
|---|---|---|---|---|---|---|---|
| | emitting | voltage | density | Luminance | Efficiency | emitting | life-span |
| | material | (V) | (mA/cm²) | (cd/m²) | (cd/A) | color | (hr @100 mA/cm²) |
| Example 1 | compound 1 | 6.4 | 50 | 2,462 | 4.9 | blue | 245 hr |
| Example 2 | compound 2 | 6.5 | 50 | 2,564 | 5.1 | blue | 262 hr |
| Example 3 | compound | 6.3 | 50 | 2,431 | 4.8 | blue | 258 hr |
| | 10 | | | | | | |
| Example 4 | compound | 6.4 | 50 | 2,643 | 5.2 | blue | 271 hr |
| | 18 | | | | | | |
| Example 5 | compound | 6.1 | 50 | 2,574 | 5.1 | blue | 253 hr |
| | 22 | | | | | | |
| Example 6 | compound | 6.2 | 50 | 2,460 | 4.9 | blue | 248 hr |
| | 27 | | | | | | |
| Example 7 | compound | 6.1 | 50 | 2,687 | 5.3 | blue | 263 hr |
| | 30 | | | | | | |
| Example 8 | compound | 6.3 | 50 | 2,634 | 5.2 | blue | 255 hr |
| | 48 | | | | | | |
| Comparative | DNA | 8.2 | 50 | 1,590 | 3.1 | blue | 124 hr |
| Example 1 | | | | | | | |

The compound according to an example embodiment of the present invention was used as a host material of a blue emission layer and improved the driving voltage and efficiency and also, remarkably improved life-span of the organic light emitting diode compared with a comparable material, DNA.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and equivalents thereof. Therefore, the aforementioned embodiments should be understood to be examples but not limiting the present invention in any way.

Description of symbols

| | |
|---|---|
| 100: organic light emitting diode | 110: cathode |
| 120: anode | 105: organic thin layer |
| 130: emission layer | 140: hole transport layer (HTL) |
| 150: electron transport layer (ETL) | 160: electron injection layer (EIL) |
| 170: hole injection layer (HIL) | 230: emission layer + electron |
| | transport layer (ETL) |

What is claimed is:

1. A compound for an organic optoelectronic device represented by the following Chemical Formula 1: 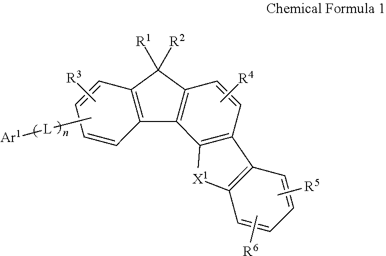
wherein, in the above Chemical Formula 1,
X¹ is —O—, —S—, or —CR^{a}R^{b}—;
Ar¹ is a substituted or unsubstituted C6 to C30 aryl group;
R¹ and R² are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; or R¹ and R² are fused with each other to form a ring;
R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group;
L is a substituted or unsubstituted C6 to C30 arylene group; and
n is an integer from 0 to 3.

2. The compound for an organic optoelectronic device of claim 1, wherein the compound for an organic optoelectronic device is represented by the following Chemical Formula 2: 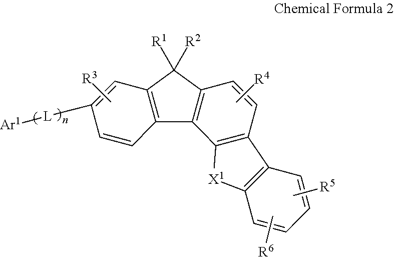
wherein, in the above Chemical Formula 2,
X¹ is —O—, —S—, or —CR^{a}R^{b}—;
Ar¹ is a substituted or unsubstituted C6 to C30 aryl group;
R¹ and R² are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group; or R¹ and R² are fused with each other to form a ring;
R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group;
L is a substituted or unsubstituted C6 to C30 arylene group; and
n is an integer from 0 to 3.

3. The compound for an organic optoelectronic device of claim 1, wherein the compound for an organic optoelectronic device is represented by the following Chemical Formula 3: 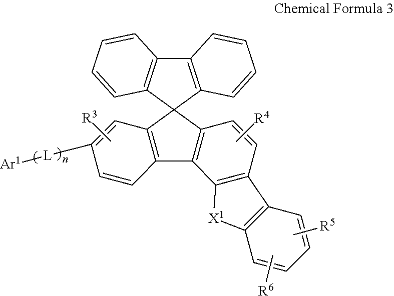
wherein, in the above Chemical Formula 3,
X¹ is —O—, —S—, or —CR^{a}R^{b}—;
Ar¹ is a substituted or unsubstituted C6 to C30 aryl group;
R^{a}, R^{b} and R³ to R⁶ are each independently hydrogen, deuterium, a substituted or unsubstituted C1 to C30 alkyl group, a substituted or unsubstituted C3 to C30 cycloalkyl group, a substituted or unsubstituted C6 to C30 aryl group, or a substituted or unsubstituted silyl group;
L is a substituted or unsubstituted C6 to C30 arylene group; and
n is an integer from 0 to 3.

4. The compound for an organic optoelectronic device of claim 1, wherein
n is an integer of 1 to 3; and
L is represented by the following Chemical Formula 4:

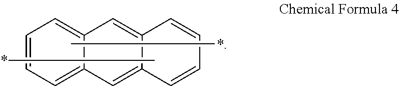

5. The compound for an organic optoelectronic device of claim 1, wherein
n is an integer of 1 to 3; and
L is represented by the following Chemical Formula 5:

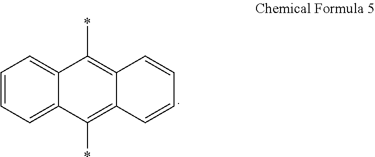 [SMILES: *c1c2ccccc2c(*)c2ccccc12]

6. The compound for an organic optoelectronic device of claim 1, wherein
n is an integer of 1 to 3; and
L is represented by the following Chemical Formula 6:

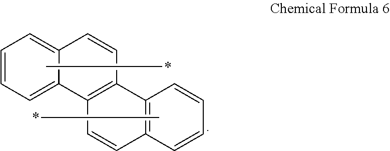

7. The compound for an organic optoelectronic device of claim 1, wherein
n is an integer of 1 to 3; and
L is represented by the following Chemical Formula 7:

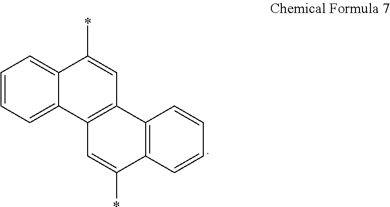 [SMILES: *c1cc2c3ccccc3c(*)cc2c2ccccc12]

8. The compound for an organic optoelectronic device of claim 1, wherein
n is an integer of 1 to 3; and
L is represented by the following Chemical Formula 8:

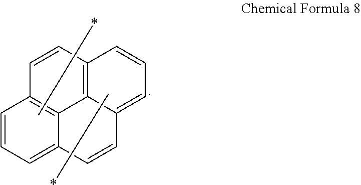

9. The compound for an organic optoelectronic device of claim 1, wherein
n is an integer of 1 to 3; and
L is represented by the following Chemical Formula 9:

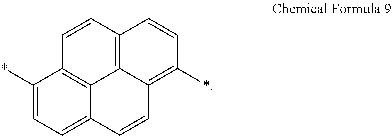

10. The compound for an organic optoelectronic device of claim 1, wherein X¹ is —S—.

11. The compound for an organic optoelectronic device of claim 1, wherein Ar¹ is a substituted or unsubstituted phenyl group, a substituted or unsubstituted biphenyl group, a substituted or unsubstituted naphthyl group, a substituted or unsubstituted anthracenyl group, or a substituted or unsubstituted phenanthrenyl group.

12. The compound for an organic optoelectronic device of claim 1, wherein Ar¹ is a silyl group, a cyano group, deuterium, a halogen, or a C6 to C30 aryl group substituted with a C1 to 10 alkyl group.

13. An organic light emitting diode, comprising
an anode;
a cathode; and
at least one of an organic thin layer between the anode and cathode,
wherein the at least one of the organic thin layer comprises the compound according to claim 1.

14. The organic light emitting diode of claim 13, wherein the organic thin layer comprises an electron injection layer (EIL), an electron transport layer (ETL), a hole injection layer (HIL), a hole transport layer (HTL), or an emission layer.

15. The organic light emitting diode of claim 13, wherein the organic thin layer is an electron injection layer (EIL), or an electron transport layer (ETL).

16. The organic light emitting diode of claim 13, wherein the organic thin layer is an emission layer.

17. The organic light emitting diode of claim 13, wherein the compound is used as a host in an emission layer.

18. The organic light emitting diode of claim 13, wherein the compound is used as a red, green, blue, or white host in an emission layer.

19. A display device comprising the organic light emitting diode according to claim 13.
